(19) United States
(12) Patent Application Publication
(10) Pub. No.: US 2019/0042666 A1
(43) Pub. Date: Feb. 7, 2019

(54) METHOD AND APPARATUS FOR SELECTING BURNISHING TOOL MODEL AND STORAGE MEDIUM STORING PROGRAM

(71) Applicant: SUGINO MACHINE LIMITED, Uozu City (JP)

(72) Inventor: Mitsuru MUTO, Uozu City (JP)

(73) Assignee: SUGINO MACHINE LIMITED

(21) Appl. No.: 15/857,747

(22) Filed: Dec. 29, 2017

(30) Foreign Application Priority Data
Aug. 4, 2017 (JP) 2017-151978

(51) Int. Cl. G06F 17/50

(52) U.S. Cl. CPC G06F 17/50; G06Q 30/0631

(57) ABSTRACT

A method for enabling a computer to select a burnishing tool model using information about customer requests input into the computer. The method for selecting a burnishing tool model include receiving a machining shape, a material, and a finished product dimension, selecting a display tool type using a display tool type selection unit, outputting the display tool type using an output unit, receiving a specified type through an input unit, outputting a branch condition using the output unit, receiving a specified condition through the input unit, selecting a selective tool model using a tool model selection unit, and outputting the selective tool model using the output unit.

### CROSS-REFERENCE TO RELATED APPLICATIONS

This application claims the benefit of priority to Japanese Patent Application No. 2017-151978, filed on Aug. 4, 2017, the entire contents of which are hereby incorporated by reference.

### BACKGROUND

### 1. Technical Field

The present invention relates to a method and an apparatus for selecting a burnishing tool model using a computer, and a storage medium storing a program.

### 2. Description of the Background

A seller offers a variety of burnishing tool types for different dimensions of finished products. Before selling a burnishing tool, a salesperson receives a drawing of a target workpiece, the model of a machine to which a burnishing tool is to be mounted, and other conditions requested from a customer. A technician then selects an appropriate burnishing tool model that satisfies the received conditions. The salesperson presents the selective tool model to the customer, and then receives an order placed when the customer is satisfied with the presented tool model.

### BRIEF SUMMARY

A burnishing tool model for achieving target finished product dimensions is typically determined based on the results of an enormous number of machining tests. The tool model selection based on the dimensions of a finished product and various conditions requested by a customer involves the skills of experienced technicians. One or more aspects of the present invention are directed to a method and an apparatus for enabling a computer to select a burnishing tool model using information about customer requests input into the computer.

A first aspect of the present invention provides a method for selecting a burnishing tool model, the method comprising:

receiving, by an input unit, a machining shape, a material, and a finished product dimension;

selecting, by a display tool type selection unit, at least one display tool type satisfying a display condition based on the input machining shape, the input material, and the input finished product dimension, and a display condition table stored in a storage unit;

receiving, by the input unit, a specified tool type selected from the at least one display tool type output from an output unit;

receiving, by the input unit, a specified condition selected from at least one branch condition assigned to the specified tool type output from the output unit based on the specified tool type and a tool model table including the at least one branch condition for selecting at least one tool model, the tool model table being stored in the storage unit;

selecting, by a tool model selection unit, a tool model as a selective tool model applicable to the machining shape, the finished product dimension, and the specified condition from the at least one tool model included in the tool model table for the specified tool type; and

outputting, by the output unit, the selective tool model.

A second aspect of the present invention provides a selection apparatus for selecting a burnishing tool model.

A third aspect of the present invention provides a storage medium storing a program for selecting a burnishing tool model.

The above aspects of the present invention allow easy selection of a burnishing tool model using a machining shape, a material, and a finished product dimension input by a customer.

### BRIEF DESCRIPTION OF DRAWINGS

FIGS. 1A to 1C are diagrams showing burnishing tool types and their methods of use.

FIG. 2 is a block diagram of an apparatus for selecting a burnishing tool model in one embodiment.

FIG. 3 is a flowchart showing a method for selecting a burnishing tool model in one embodiment.

FIG. 4 is a diagram showing an entry screen for a machining shape in one embodiment.

FIG. 5 is a diagram showing an entry screen for the dimensions of a finished product in one embodiment.

FIG. 6 is a table listing display conditions in one embodiment.

FIG. 7 is a table for calculating comparison values included in the display condition table in one embodiment.

FIG. 8 is a table showing supplemental information in one embodiment.

FIG. 9 is a diagram showing a list screen listing display tool types in one embodiment.

FIG. 10 is a diagram showing a detail screen for a type in one embodiment.

FIG. 11 is a table listing tool models in one embodiment.

FIG. 12 is a diagram showing an entry screen for branch conditions in one embodiment.

FIG. 13 is a table for calculating machining conditions in one embodiment.

FIG. 14 is a table storing formulas for calculating pre-machined product diameters in one embodiment.

FIG. 15 is a table storing formulas for calculating tool diameters in one embodiment.

FIG. 16 is a diagram showing a display screen for a selective tool model in one embodiment.

FIG. 17 is a diagram describing entry information in one embodiment.

### DETAILED DESCRIPTION

Embodiments of the present invention will now be described with reference to the drawings.

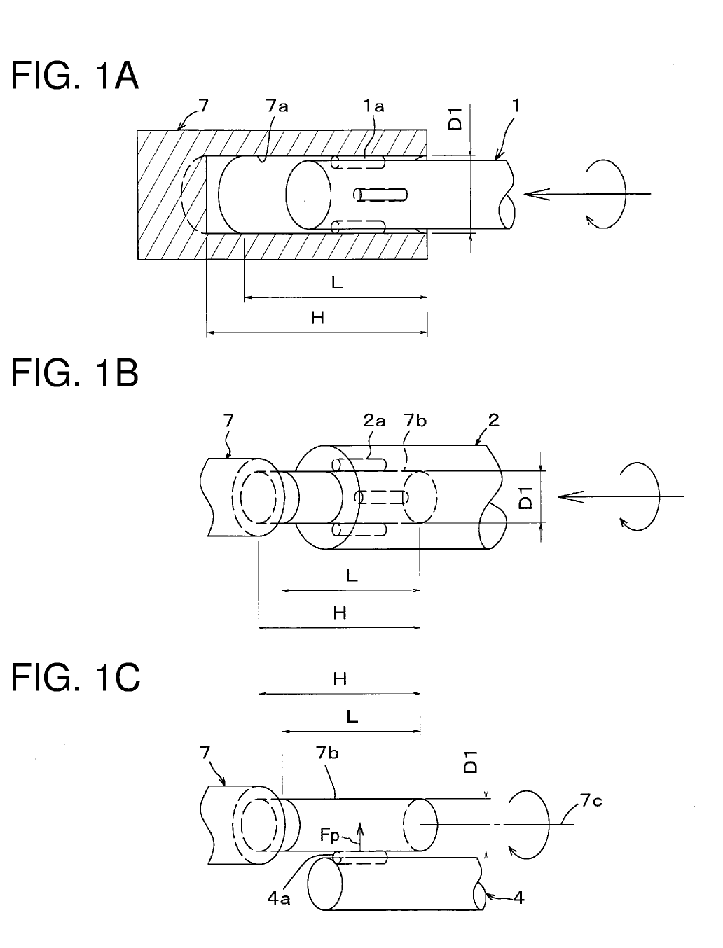

Typical burnishing tool types and their machining methods will be described first. FIG. 1A is a diagram showing a burnishing tool 1 for machining the inner surface of a workpiece defining a cylindrical space. The burnishing tool 1 includes rollers la, which are arranged at circumferentially regular intervals on an outer periphery of its distal end. The rollers la extend parallel to the axis of the tool. The burnishing tool 1 is inserted into a target hole 7a of a workpiece 7, while the burnishing tool 1 is rotating. The rollers la roll on the surface defining the target hole 7a while being pressed against the surface defining the target hole 7a. This causes the surface defining the target hole 7a to be mirror-finished. The target hole 7a after machined has its inner diameter referred to as a machined diameter D1, the length of its machined portion referred to as a machined length L, and its depth referred to as an interaction height H. The length of an unmachined portion of the target hole 7a, which corresponds to a difference between the interaction height H and the machined length L, is referred to as unmachined length H-L. The burnishing tool 1 is usable for machining performed by either rotating a workpiece or rotating the tool. The burnishing tool 1 belongs to types 11 and 12 described below.

FIG. 1B is a diagram showing a burnishing tool 2 for machining the outer surface of a cylindrical workpiece. The burnishing tool 2 includes rollers 2a, which are arranged at circumferentially regular intervals on an inner periphery of its distal end. The rollers 2a extend parallel to the axis of the tool. The rollers 2a roll while being pressed against the outer surface of a target shaft 7b. This causes the surface of the target shaft 7b to be mirror-finished. The target shaft 7b after machined has its outer diameter referred to as a machined diameter D1, the length of its machined portion referred to as a machined length L, and its entire length referred to as an interaction height H. The burnishing tool 2 is usable for machining performed by either rotating a workpiece or rotating the tool. The burnishing tool 2 belongs to type 21 described below.

FIG. 1C is a diagram showing a burnishing tool 4 with a single roller. The burnishing tool 4 is sold as a single-roller (SR) burnishing tool (Sugino Machine Limited). A workpiece 7 rotates about a rotation axis 7c. The burnishing tool 4 includes a rotatable roller 4a on its distal end. The roller 4a is arranged parallel to the rotation axis 7c. The roller 4a is pressed against the surface of the target shaft 7b of the rotating workpiece 7 under a preload (pressure) Fp, while it is rolling on the surface of the target shaft 7b. This causes the surface of the target shaft 7b to be mirror-finished. The burnishing tool 4 belongs to types 41 and 42 described below.

Although the three models of burnishing tools are described above, a selection apparatus 10 or a method for selecting a burnishing tool (described later) allows selection from a variety of burnishing tools for different machining shapes.

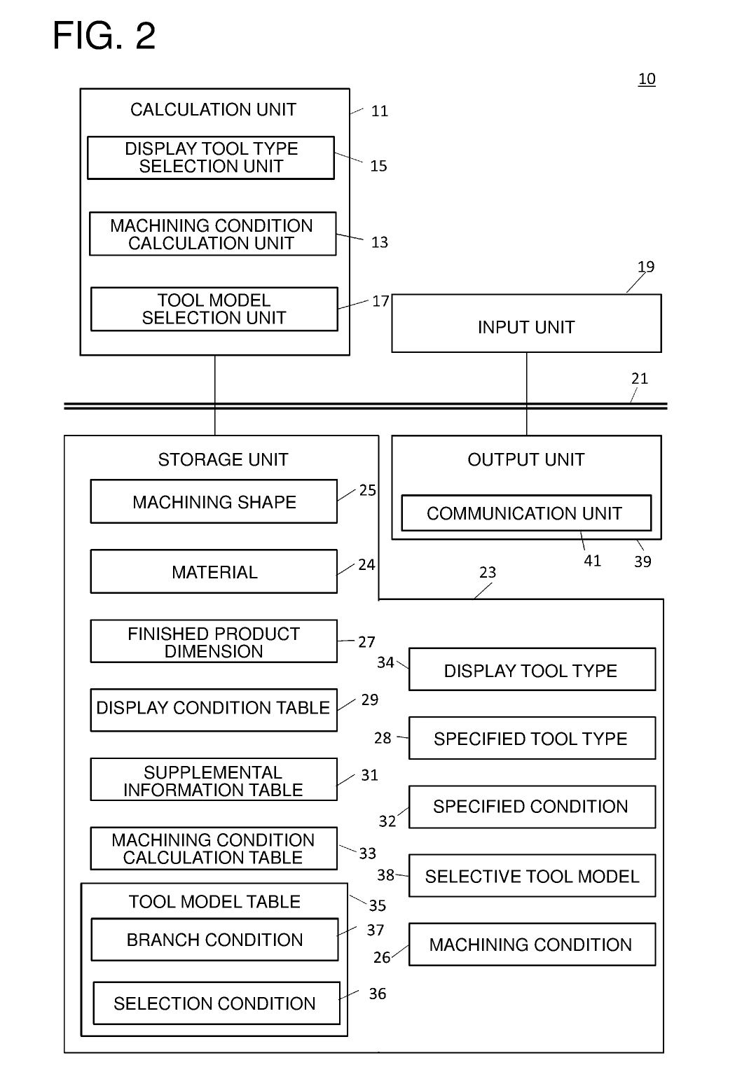

The selection apparatus 10 for selecting a burnishing tool according to one embodiment will now be described with reference to FIG. 2. The selection apparatus 10 includes a storage unit 23, a calculation unit 11, an input unit 19, an output unit 39, and a bus 21. The storage unit 23 includes a main memory and a mass storage. The calculation unit 11 includes a central processing unit. The input unit 19 includes a keyboard, a mouse, a touch panel, or another pointing device. The output unit 39 includes a display, a printer, or another output device. The output unit 39 may include a communication unit 41. The communication unit 41 can be connected to the Internet or a telephone network to transmit and receive information through the network. The bus 21 interconnects the calculation unit 11, the storage unit 23, the input unit 19, and the output unit 39.

The storage unit 23 stores a display condition table 29, a machining condition calculation table 33, and a tool model table 35. The tool model table 35 includes at least one branch condition 37. The tool model table 35 may include at least one selection condition 36. The storage unit 23 stores at least one display tool type 34, a selective tool model 38, and at least one machining condition 26, which are obtained by calculations. The storage unit 23 stores a machining shape 25, a material 24, finished product dimensions 27, at least one specified tool type 28, and at least one specified condition 32, which are input by a customer through the input unit 19. The specified tool types 28 are specified by the customer selectively from the display tool types 34. The specified conditions 32 are specified by the customer selectively from the branch conditions 37. The storage unit 23 may further store a supplemental information table 31.

The calculation unit 11 includes a display tool type selection unit 15, a machining condition calculation unit 13, and a tool model selection unit 17. The display tool type selection unit 15 selects at least one display tool type 34 applicable to the material 24, the machining shape 25, and the finished product dimensions 27 input by the customer based on the material 24, the machining shape 25, the finished product dimensions 27, and the display condition table 29, which are stored. The tool model selection unit 17 selects a selective tool model 38, which is one of the models included in the specified tool types 28, from the tool model table 35 based on the machining shape 25, the material 24, the finished product dimensions 27, the specified tool type 28, and the specified conditions 32 input by the customer. The machining condition calculation unit 13 calculates the machining conditions 26 based on the machining shape 25, the material 24, the finished product dimensions 27, the specified tool type 28, the specified conditions 32, and the machining condition calculation table 33.

The output unit 39 outputs an entry screen 51 for each machining shape, an entry screen 53 for the dimensions of each finished product, and an entry screen 56 for branch conditions to allow the customer to easily input the machining shape 25, the material 24, the finished product dimensions 27, and the specified conditions 32.

The output unit 39 outputs a list screen 54, a detail screen 55, and a display screen 57. The list screen 54 shows the at least one display tool type 34. The detail screen 55 shows detailed information about each display tool type 34. The display screen 57 shows the selective tool model 38, a drawing for the burnishing tool of the selective tool model 38, and its machining conditions 26.

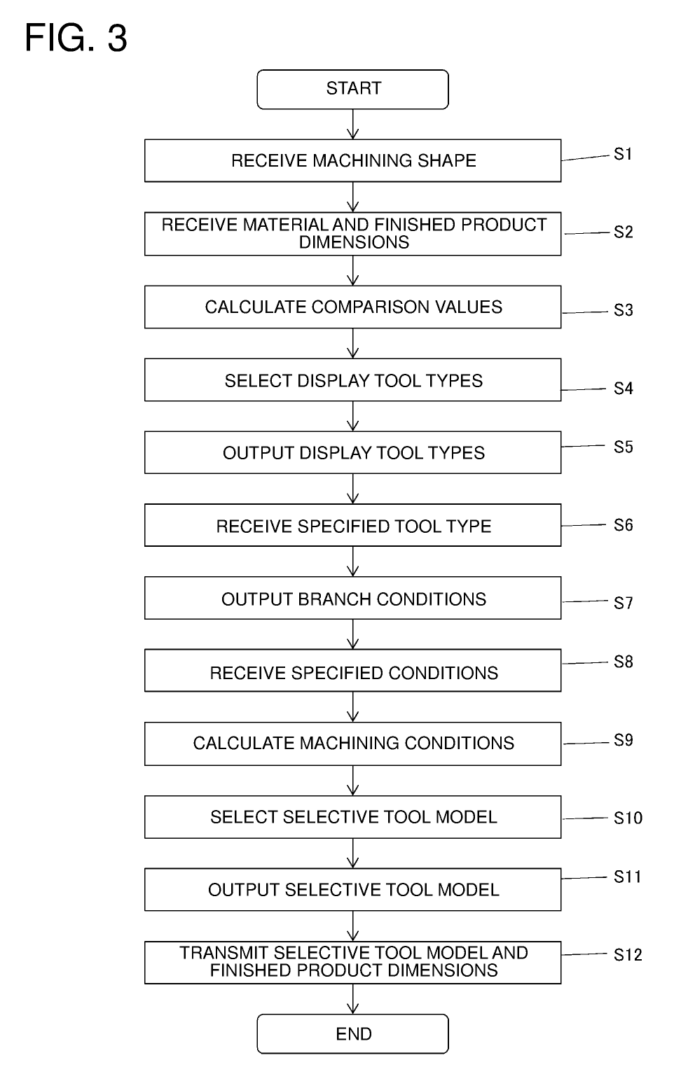

Referring now to FIG. 3, a method for selecting a burnishing tool model according to the present embodiment will be described. The input unit 19 receives the machining shape 25 (S1). The input unit 19 receives the material 24 and the finished product dimensions 27 (S2). The display tool type selection unit 15 calculates the comparison values for the display condition table 29 based on the machining shape 25, the material 24, and the finished product dimensions 27 (S3). The display tool type selection unit 15 then selects at least one display tool type 34 by comparing the machining shape 25, the material 24, and the finished product dimensions 27 with the corresponding comparison values (S4). The output unit 39 outputs the display tool types 34 on the list screen 54 (S5). The input unit 19 receives the specified tool type 28 (S6). The output unit 39 outputs the branch conditions 37 on the entry screen 56 (S7). The input unit 19 receives the specified conditions 32 (S8). The machining condition calculation unit 13 calculates the machining conditions 26 based on the machining shape 25, the material 24, the finished product dimensions 27, the specified tool type 28, the specified conditions 32, and the machining condition calculation table 33 (S9). The tool model selection unit 17 selects the selective tool model 38 based on the machining shape 25, the material 24, the finished product dimensions 27, the specified conditions 32, the specified tool type 28, and the tool model table 35 (S10). The output unit 39 outputs the selective tool model 38 (S11). The communication unit 41 transmits the selective tool model 38 and the finished product dimensions 27 based on entry information 59 (S12).

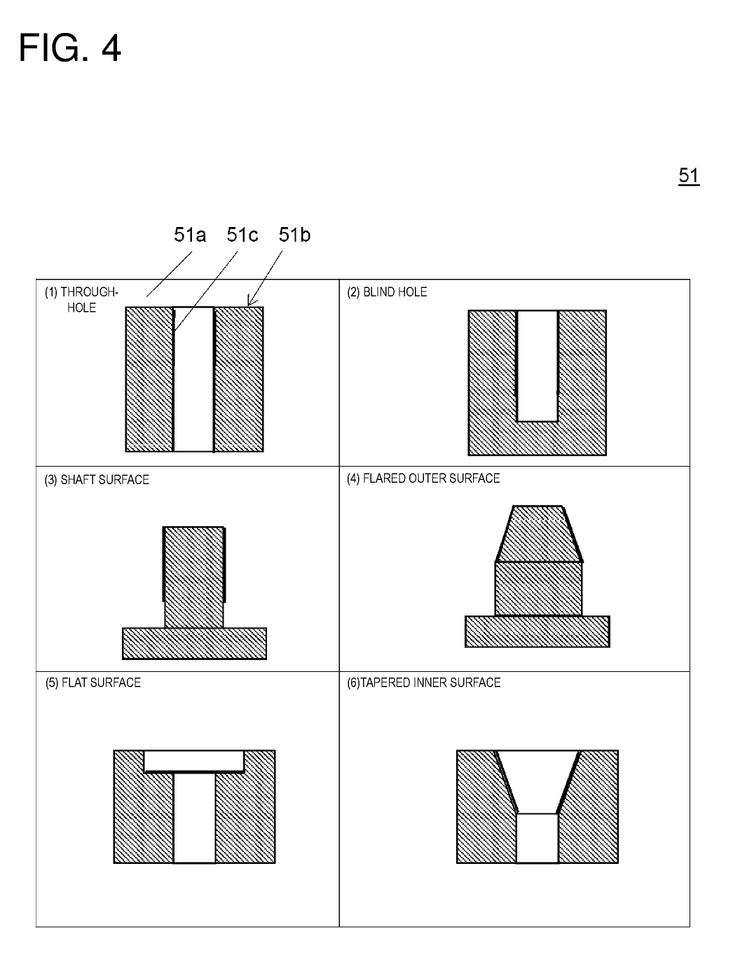

Referring to FIG. 4, step 51 will be described. FIG. 4 is a diagram describing an entry screen for a machining shape. The output unit 39 displays the entry screen 51. The entry screen 51 shows a plurality of machining shapes 25. Each machining shape 25 is represented by words 51a and/or a machining shape image 51b. In FIG. 4, the machining shape is represented by both the words 51a and the machining shape image 51b. The words 51a may include a number. The machining shape image 51b is a cross-sectional view of the shape of a machined part, which is indicated by a bold line 51c.

The customer refers to the entry screen 51, and inputs the machining shape 25 by inputting the words 51a with a keyboard, which is the input unit 19. The customer may input the machining shape 25 by inputting the corresponding number. The customer may select the machining shape image 51b using a pointing device, which is as the input unit 19, and inputs the machined shape 25. The storage unit 23 stores the input machining shape 25.

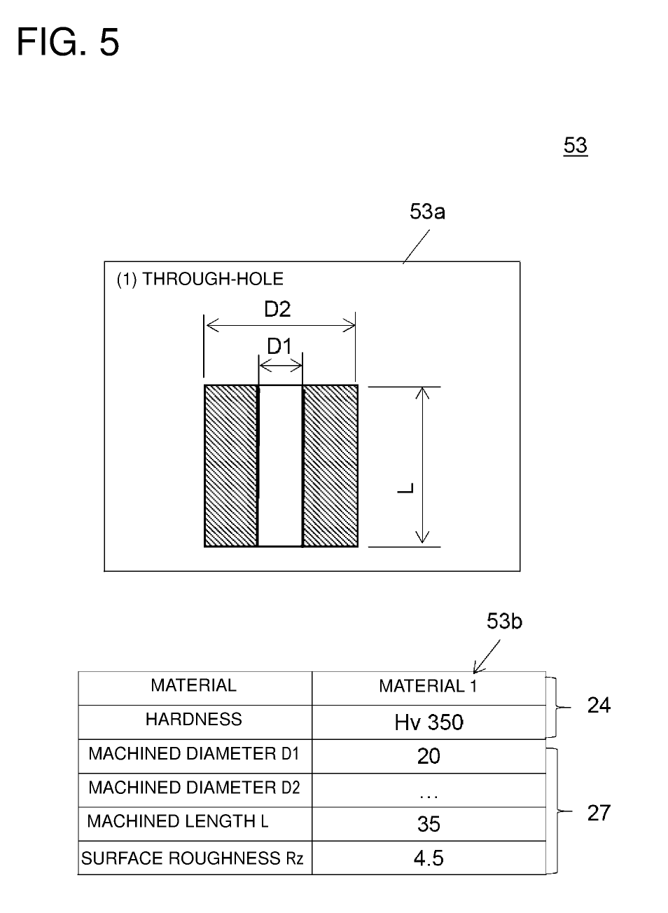

Referring to FIG. 5, step S2 will be described. FIG. 5 shows an entry screen 53 that appears when the customer selects (1) through-hole as the machining shape 25. The entry screen 53 includes a dimension display area 53a and a dimension entry area 53b. The dimension display area 53a shows a drawing illustrating the dimensions to be input in accordance with the machining shape 25.

The dimension entry area 53b prompts an input of the material 24 and the finished product dimensions 27 included in the dimension display area 53a. The material 24 includes at least one item from the material name, the material symbol, and the hardness. In some embodiments, the material 24 may be specified from multiple options for the material name, the material symbol, and the hardness. The customer may select one of the options and input the material 24 using the input unit 19. The finished product dimensions 27 can be input freely. The entry screen 53 may show input ranges for the finished product dimensions 27.

When the finished product dimensions 27 are input, a surface roughness Rz before machining may also be input, or a surface roughness Ra may be input instead of the surface roughness Rz.

The calculation unit 11 displays the entry screen 53 in accordance with the machining shape 25. The calculation unit 11 can display the entry screen 53 excluding unneeded dimensions in accordance with the machining shape 25. The input unit 19 may also be designed not to accept any unneeded dimensions input from the customer.

The storage unit 23 stores the input material 24 and the input finished product dimensions 27.

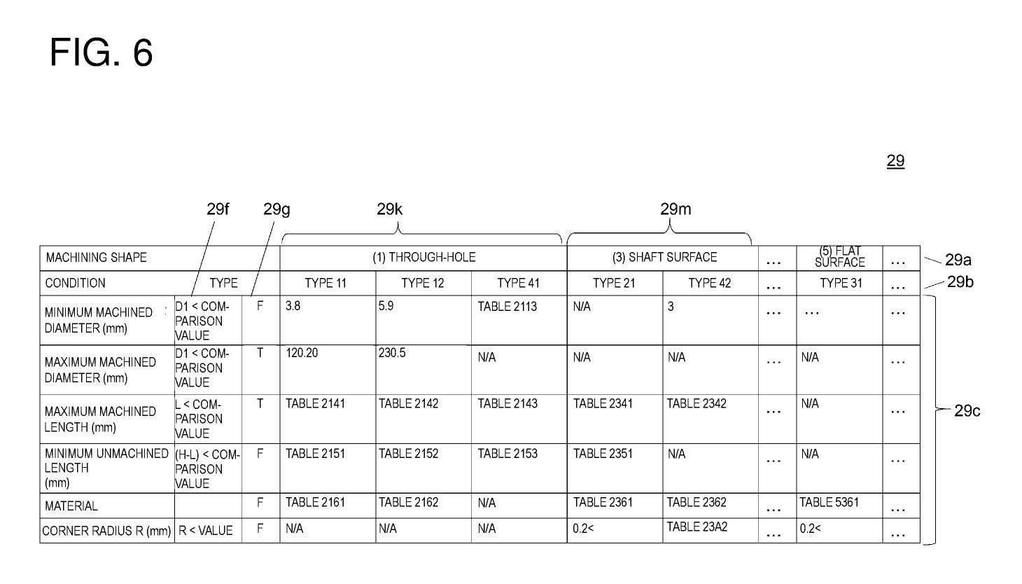

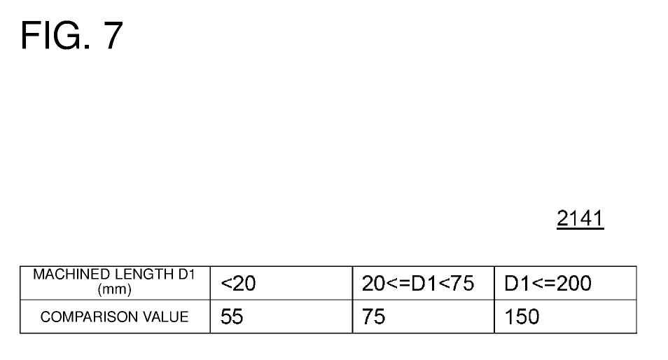

Referring now to FIGS. 6 and 7, steps S3 and S4 will be described. The display condition table 29 shown in FIG. 6 includes a plurality of display conditions for each machining shape 25 and for each tool type. A row 29a stores each machining shape 25. A row 29b stores tool types applicable to each machining shape 25 in the row 29a. A row 29c stores at least one display condition corresponding to each tool type. A plurality of display conditions may be defined for each tool type. A column 29f stores relation conditions to be used for comparing the finished product dimensions 27 with the corresponding comparison values shown in columns 29k, 29m, and subsequent columns. A column 29g stores display conditions. The column 29g stores T for each condition satisfying the corresponding relation condition shown in the column 29f, and stores F for each condition dissatisfying the corresponding relation condition. The columns 29k, 29m, and subsequent columns show the comparison values for each tool type in the column 29f.

Each comparison value in the column 29k may be one of N/A, a numerical value, a value indicating a comparison value calculation table, or a value indicating a comparison value calculation function. For the tool type for which the column 29k stores N/A, the condition in the corresponding row is not available for comparison. For the tool type for which the column 29k stores a numerical value, the numerical value is used as a comparison value. For the tool type for which the column 29k stores a value indicating the comparison value calculation table or the comparison value calculation function, the table or the function is used to obtain the comparison value. The comparison value calculation table is defined for the material 24 or the finished product dimensions 27. The comparison value calculation table may include formulas or functions in its cells. The comparison value calculation function is a function using the material 24 or the finished product dimensions 27 as an argument. As shown in FIG. 6, the display condition table 29 may include, in its cells, a table number indicating a comparison value calculation table or a function number indicating a comparison value calculation function.

The display condition table 29 may use display conditions that may either satisfy or dissatisfy the corresponding relation conditions. In this case, the display condition table 29 may eliminate the column 29g storing the display conditions, and the relation conditions are used as the display conditions.

Step S3 will be described. The display tool type selection unit 15 reads the machining shape 25, the material 24, and the finished product dimensions 27 from the storage unit 23. The display tool type selection unit 15 inputs the material 24 and the machining shape 25 into the comparison value calculation table or the comparison value calculation function, and obtains comparison values for all the cells of the column corresponding to the machining shape 25. For a cell storing either a numerical value or N/A as a comparison value, the display tool type selection unit 15 does not calculate a comparison value.

For the machining shape 25 that is (1) through-hole, the display tool type selection unit 15 calculates comparison values included in the column 29k. For the tool type 11, for example, the maximum machined length is the table 2141. The display tool type selection unit 15 refers to the table 2141, which is shown in FIG. 7. The table 2141 includes comparison values defined for the three ranges of the machined diameter D1. In the table, the symbol <= represents being greater than or equal to. The display tool type selection unit 15 reads the machined diameter D1 from the finished product dimensions 27. When, for example, the machined diameter D1 is 5 mm, the display tool type selection unit 15 obtains the comparison value of 55.

Referring now to FIG. 6, step S4 will be described. The display tool type selection unit 15 selects, as the display tool types 34, tool types satisfying all the corresponding display conditions shown in the row 29c, among the tool types included in the row 29b corresponding to each machining shape 25. The display tool type selection unit 15 determines each cell including N/A as a comparison value to satisfy the corresponding display condition.

For example, the minimum machined diameter D1 min for the machining shape 25 that is (1) through-hole with the machined diameter D1 of 5 mm will now be described. For the tool type 11, the relation condition is D1<the comparison value, the comparison value for the minimum machined diameter is 3.8 mm, and the display condition is F. In this cell, the machined diameter D1 in the machined shape 25 is greater than 3.8 mm, and thus dissatisfies D1<3.8. The display condition is F, which is thus satisfied. When the display conditions included in the other rows are all satisfied in the same manner, the display tool type selection unit 15 selects the tool type 11 as the display tool type 34.

For the tool type 12, the comparison value for the minimum machined diameter D1 min is 5.9. This value satisfies the relation condition of D1<5.9. The display condition F is then dissatisfied. The tool type 12 is not included in the display tool type 34.

The comparison value for the maximum machined length L max of the tool type 11 will be described. For the tool type 11 having the machining shape 25 as (1) through-hole, the comparison value is the table 2141 (referred to FIG. 7). The comparison value corresponding to D1=5 mm is 55 mm. When, for example, the machined length L in the finished product dimensions 27 is 53 mm, the condition L<55 is satisfied. The display condition is T, and thus the tool type 11 also satisfies the display condition for the maximum machined length L max.

The processing in step S3 and the processing in step S4 may be performed in parallel. For example, the calculation (S3) and the comparison (S4) of comparison values for the cells in the display condition table 29 may be performed for each column corresponding to the machining shape 25. When a cell dissatisfies its corresponding display condition, the display tool type selection unit 15 may determine to hide the tool types corresponding to the cell dissatisfying the display condition. For any tool type to be hidden and also with a comparison value that has yet to be calculated, the calculation for the comparison value may be canceled.

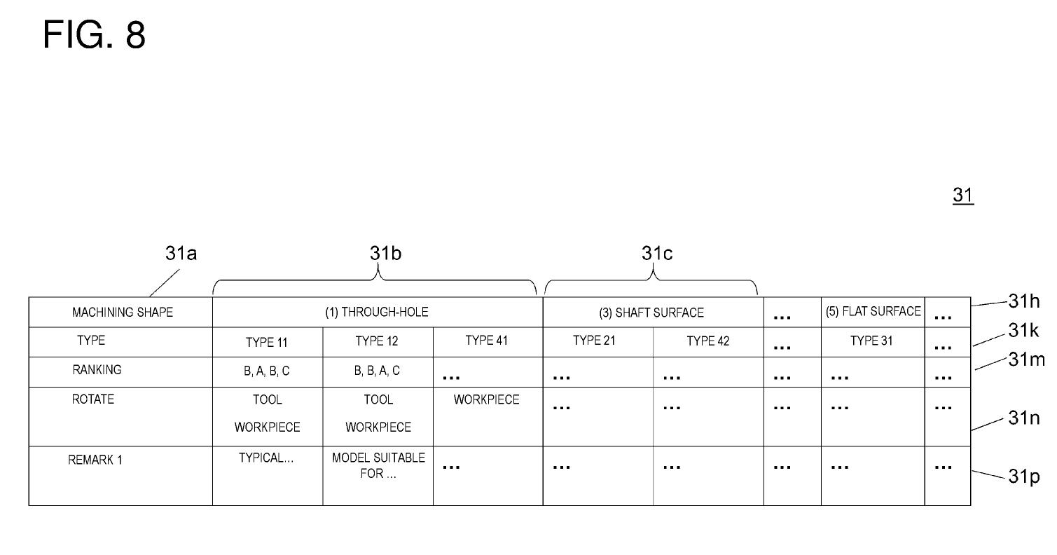

Step S5 will be described with reference to FIGS. 8 to 10. FIG. 8 shows the supplemental information table 31 storing supplemental information for each tool type corresponding to the machining shape 25. A column 31a stores each item. Columns 31b, 31c, and subsequent columns store supplemental information for tool types corresponding to the machining shape 25. A row 31h stores the machining shapes 25. A row 31k stores tool types applicable to the machining shapes 25 in the row 31h. A row 31m stores a ranking. The ranking including the ratings of the initial cost, the running cost, the machining speed, and the versatility. A row 31n indicates whether each tool type stored in the row 31k is applicable to machining using the rotating tool or machining using the rotating workpiece. A row 31p may include a comment briefly describing the tool type stored in the row 31k.

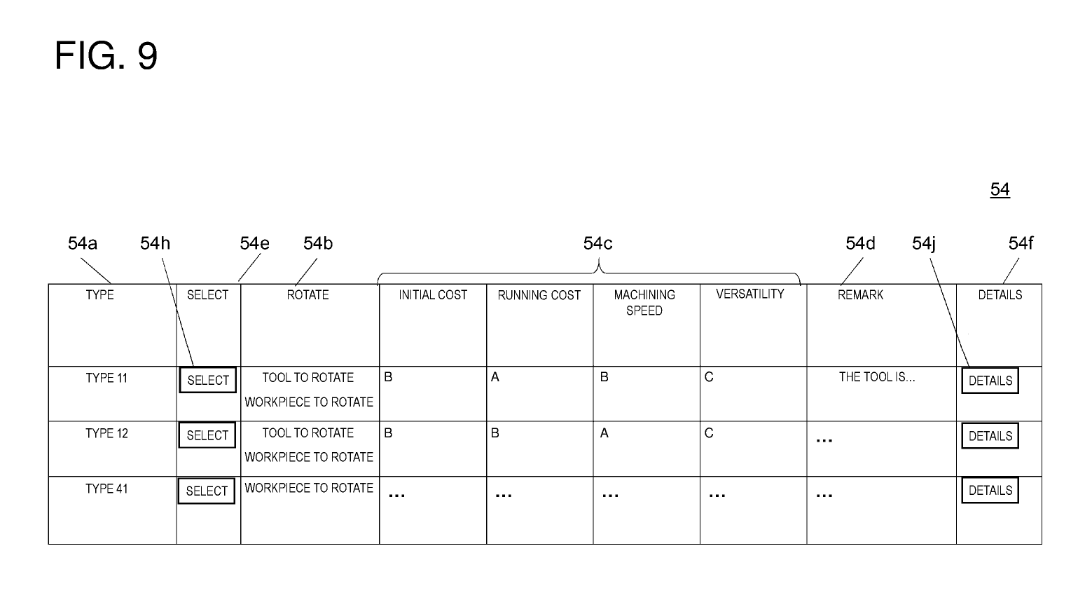

FIG. 9 shows the list screen 54. The list screen 54 shows the display tool types 34 in each row. A column 54a includes each tool type name. The column 54a may include the external views of each tool type. A column 54e stores a select button 54h. A column 54b indicates whether each tool type stored in the column 54a is applicable to machining using the rotating tool or machining using the rotating workpiece. A column 54c stores a ranking. A column 54d stores a remark for each tool type in the column 54a. A column 54f stores a detail button 54j for displaying details. The column 54f may be eliminated.

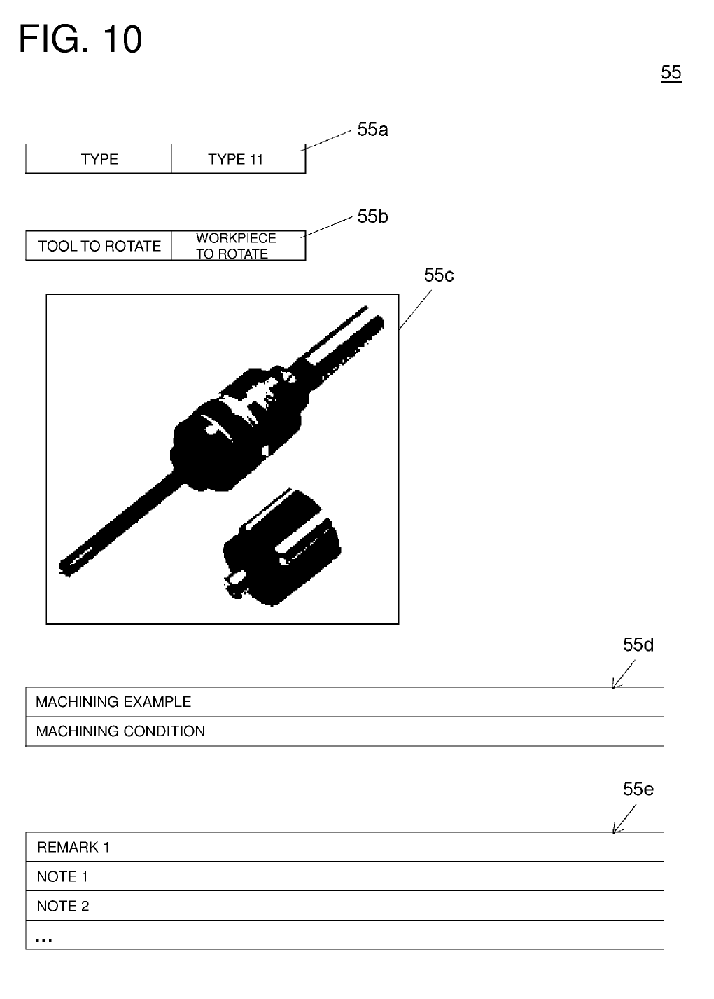

When the detail button 54j is clicked using the input unit 19, the output unit 39 displays the detail screen 55 (refer to FIG. 10) for the tool type of the clicked detail button 54j. The detail screen 55 may show a tool type name 55a, a rotation mode 55b, which indicates an applicable mode selected from machining using the rotating tool and machining using the rotating workpiece, an external view 55c, a machining example 55d, and a note 55e. The detail screen 55 may further include other information such as the characteristics of the tool type, an actuator to be used, related videos, related technical documents, or FAQs.

The detail screen 55 may include a return button (not shown). When the return button is clicked, the output unit 39 displays the list screen 54 again.

Step S6 will be described with reference to FIG. 9. When the select button 54h is clicked using the input unit 19, the selection apparatus 10 receives the tool type corresponding to the clicked select button 54h as the specified tool type 28. The storage unit 23 stores the received specified tool type 28.

The list screen 54 may not include the select button 54h. The detail screen 55 may include the select button 54h.

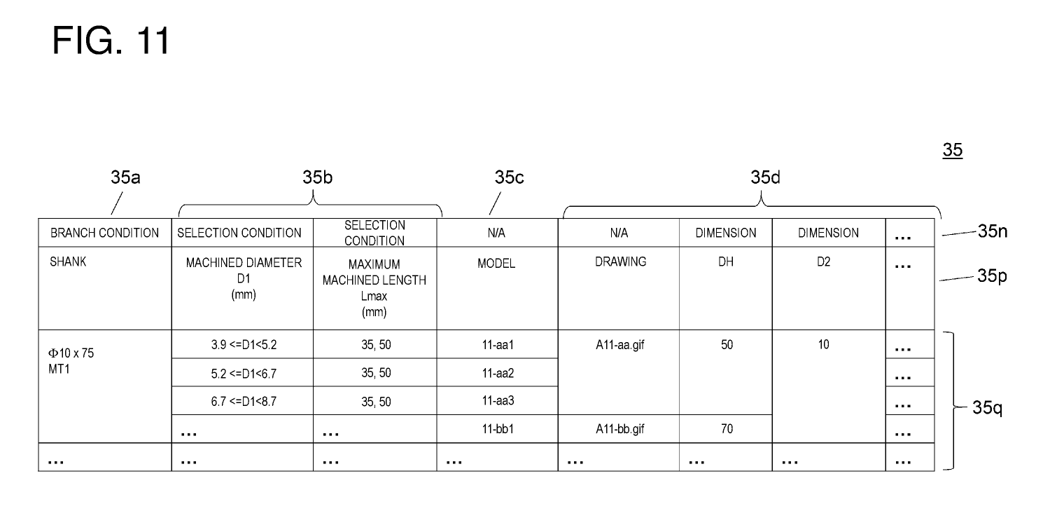

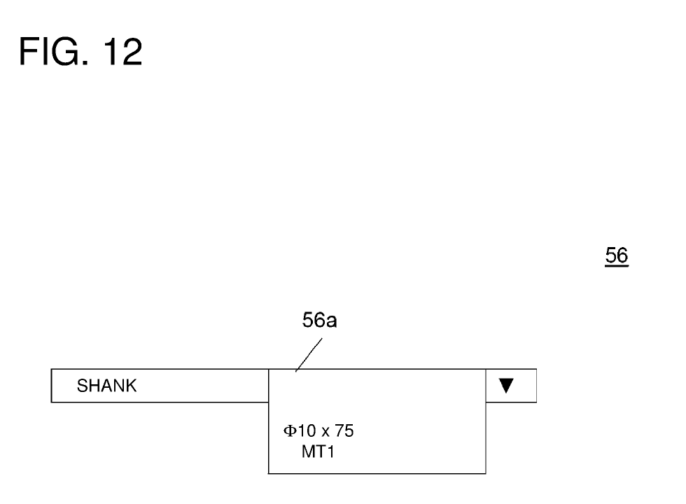

Step S7 will be described with reference to FIGS. 11 and 12. The storage unit 23 stores the tool model table 35 including information about all tool types that are available. The tool model table 35 may include machining conditions specific to each tool model. The machining conditions may be determined using a machining condition calculation table or a machining condition calculation formula.

The calculation unit 11 reads the tool model table 35 corresponding to the specified tool type 28 from the storage unit 23. The calculation unit 11 also reads the machining shape 25, the material 24, and the finished product dimensions 27, which are associated with the branch conditions 37 in the tool model table 35, from the storage unit 23. The calculation unit 11 then searches for the branch conditions 37 corresponding to the specified tool type 28, the machining shape 25, the material 24, and the finished product dimensions 27. The calculation unit 11 outputs the retrieved branch conditions 37 to the output unit 39. The calculation unit 11 causes the output unit 39 to output the corresponding number of branch conditions 37 included in the tool model table 35.

FIG. 11 shows the tool model table 35 for the tool type 11. A row 35n stores the correspondence of each column to one of the branch conditions 37, the selection conditions 36, and the dimensions. In the table, N/A indicates the cell corresponding to no item. The selection conditions 36 are used by the tool model selection unit 17 to select one of the tool models included in the tool model table 35 as the selective tool model 38. The selection conditions 36 indicate the applicable ranges of the machining shape 25, the material 24, the finished product dimensions 27, and the machining conditions 26. A row 35p stores display items. A row 35q stores at least one tool model. A column 35a stores the branch conditions 37. The tool model table 35 includes shank types as the branch conditions 37. The selection conditions 36 in a column 35b include the applicable range of the machined diameter D1, and the maximum machined length L max. The applicable range of the machined diameter D1 includes an applicable width of the machined diameter D1, which is greater than or equal to the minimum machined diameter D1 min and smaller than the maximum machined diameter D1 max. A column 35c stores tool models. A column 35d stores drawings for the burnishing tool models in the column 35c and their dimensions.

The column 35d may include a dimension calculation formula instead of the dimensions. The dimension calculation formula is used to calculate the dimensions for the material 24 and the finished product dimensions 27.

FIG. 12 shows the entry screen 56 for the tool type 11. The entry screen 56 shows at least one branch condition 37 specified in the tool model table 35 for the specified tool type 28. As shown in the tool model table 35, the tool type 11 has one branch condition 37. Thus, the entry screen 56 includes a single pulldown input 56a, which indicates the branch condition. The pulldown input 56a shows the branch conditions included in the column 35a in the tool model table 35.

Although the entry screen 56 shows the branch conditions 37 in a pulldown, each branch condition 37 may appear in a different screen. Each branch condition may appear with a radio button. In this case, radio buttons are selected to input the specified condition 32 in step S8.

The processing in step S7 may be performed in parallel with the processing in step S9. The processing in step S9 may be performed before the processing in step S7. For example, at least one of the machining conditions 26 may be used as the selection conditions 36. In this case, the tool model selection unit 17 may select branch conditions to be presented to the customer in accordance with the result of the machining condition calculation performed in step S9.

In step S7, the calculation unit 11 may avoid displaying any branch condition unselectable for the machining shape 25, the material 24, and the finished product dimensions 27, among the branch conditions 37 included in the tool model table 35.

Step S8 will be described with reference to FIG. 12. A customer inputs the specified conditions 32, which are branch conditions specified from the branch conditions 37 displayed by the output unit 39, using the input unit 19. The customer then selects the specified conditions 32 using the pulldown input 56a. When the table includes a plurality of branch conditions 37, the customer inputs a specified condition 32 for each of all the displayed branch conditions 37. The selection apparatus 10 then receives the input specified conditions 32. The input specified conditions 32 are stored into the storage unit 23.

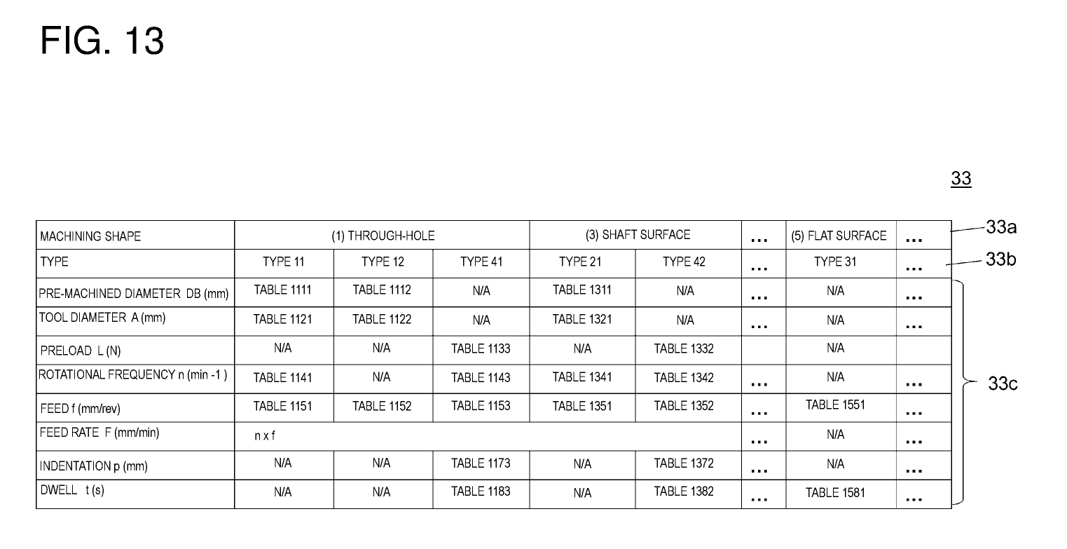

Step S9 will be described with reference to FIGS. 13 to 15. The machining condition calculation unit 13 reads at least one item from the machining shape 25, the material 24, the finished product dimensions 27, the specified tool type 28, and the specified conditions 32 from the storage unit 23. The machining condition calculation unit 13 then calculates, for the specified tool type 28, the machining conditions 26 by referring to the machining condition calculation table 33 based on the machining shape 25, the material 24, the finished product dimensions 27, the specified tool type 28, and the specified conditions 32. The machining condition calculation table 33 includes a formula for calculating the machining conditions 26. The machining condition calculation table 33 may include a machining condition calculation table or a machining condition calculation formula for each machining condition 26. The machining condition calculation formula is a function using at least one item from the machining shape 25, the material 24, the finished product dimensions 27, and the specified condition 32 as an argument. The machining condition calculation table is a table storing at least one item from the machining shape 25, the material 24, the finished product dimensions 27, and the specified conditions 32, and stores functions or numerical values. The storage unit 23 stores the calculated machining conditions 26.

When the tool model table 35 includes the machining condition calculation table or the machining condition calculation formula, the machining condition calculation unit 13 calculates the machining conditions included in the tool model table 35 in the same manner as described above.

FIG. 13 shows the machining condition calculation table 33. A row 33a stores machining shapes. A row 33b stores tool types that can be used for each machining shape in the row 33a. A row 33c indicates the machining conditions for each tool type in the row 33b using a number representing a machining condition calculation table, a machining condition calculation formula, or a numerical value. In the table, N/A indicates that the machining condition in the cell is not applicable to the corresponding tool type.

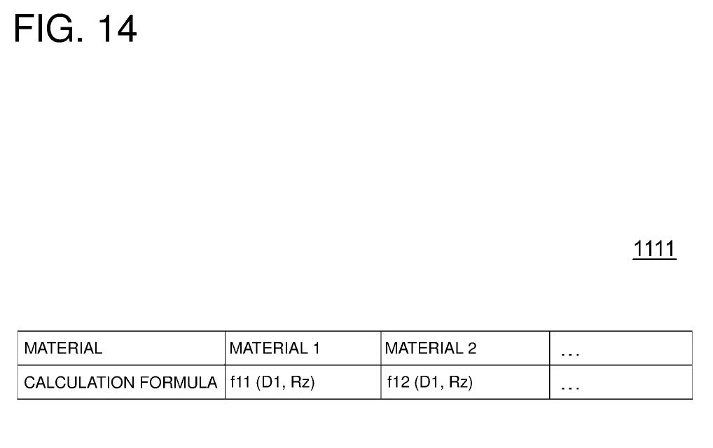

For the tool type 11 having the machining shape of (1) through-hole, the pre-machined diameter DB is a table 1111. The pre-machined diameter DB is the diameter of a target workpiece before burnishing in cylindrical surface machining. As shown in FIG. 14, the table 1111 stores the functions f11, f12, . . . for the corresponding materials 24. The functions f11, f12, . . . each use the machined diameter D1 and the surface roughness Rz as their arguments. For the material 1 with the function f11, the machining condition calculation unit 13 substitutes the machined diameter D1 and the surface roughness Rz into the function f11 to obtain the pre-machined diameter DB.

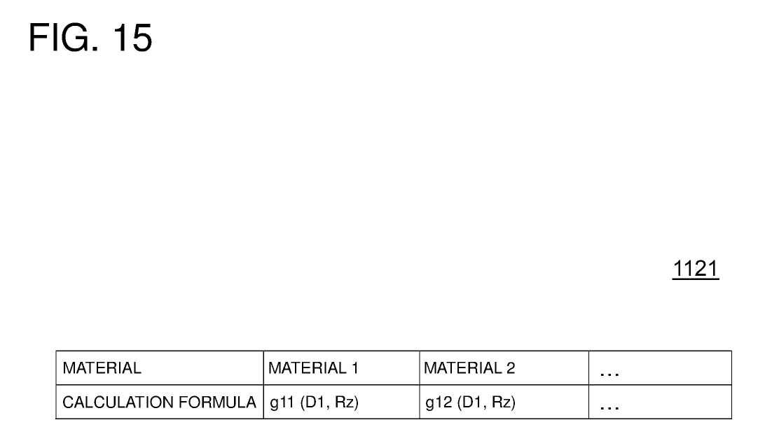

For the tool type 11 having the machining shape of (1) through-hole, the tool diameter A stores a table 1121. The tool diameter A is the diameter of a burnishing tool used in cylindrical surface machining. As shown in FIG. 15, the table 1121 stores the functions g11, g12, . . . each using the machined diameter D1 and the surface roughness Rz as their arguments for determining the tool diameter A for each material 24.

Step S10 will be described with reference to FIG. 11. The tool model selection unit 17 reads the tool model table 35 corresponding to the specified tool type 28 from the storage unit 23. The tool model selection unit 17 then reads, from the storage unit 23, the machining shape 25, the material 24, the finished product dimensions 27, the specified conditions 32, and the machining conditions 26 corresponding to each selection condition 36 shown in the read tool model table 35. For each selection condition 36 shown in the tool model table 35, the tool model selection unit 17 selects tool models that satisfy all the specified conditions 32 and the selection conditions 36.

The processing for the tool type 11 will be described. The tool model selection unit 17 compares the machined diameter D1 and the machined length L with the applicable ranges of the machined diameter D1 and the maximum machined length L max as the selection conditions 36 (shown in the column 35b), and selects applicable tool models.

The applicable range of the tool diameter A can be used as the selection conditions 36, instead of the applicable range of the machined diameter Dl. In this case, the tool model selection unit 17 reads the tool diameter A from the machining conditions 26, and compares the tool diameter A with the applicable range.

The tool model selection unit 17 can also determine a specification item. The specification item can be included in the selective tool model 38. For the maximum machined length L max, the tool model selection unit 17 can select a value greater than the machined length L and is the smallest as the maximum machined length L max. In this case, the tool model selection unit 17 includes the maximum machined length L max=35 as the specification item.

When the selection conditions 36 includes no machining conditions 26, the tool model selection unit 17 does not read any machining conditions 26 in step S10. In this case, step S9 may be eliminated.

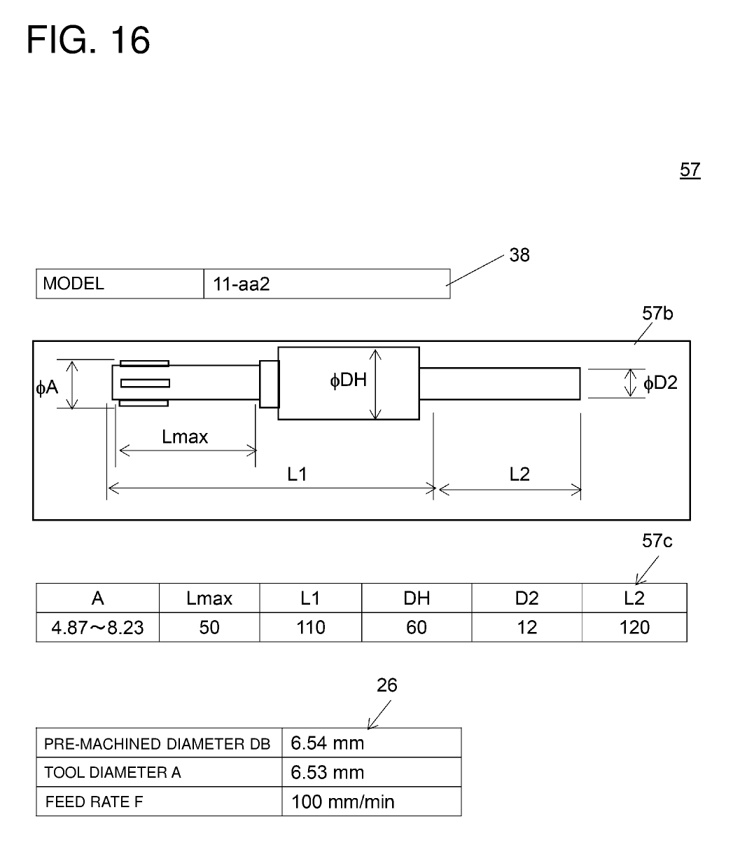

Step S11 will be described with reference to FIG. 16. The calculation unit 11 outputs the selective tool model 38 stored in the storage unit 23 to the output unit 39. In some embodiments, the calculation unit 11 displays a drawing or the machining conditions 26 for the selective tool model 38 together with the selective tool model 38.

The calculation unit 11 reads the selective tool model 38, the tool model table 35, and the machining conditions 26 to display them on the display screen 57. The display screen 57 shows the selective tool model 38, a projection drawing 57b of the selective tool model 38, a dimension table 57c, and the machining conditions 26. The output unit 39 displays the display screen 57.

With the display screen 57 including the machining conditions 26, a customer can predict the dimensions of the workpiece 7 before burnishing, the machining time, the specifications of the machine to be used, or the peripheral device to be used.

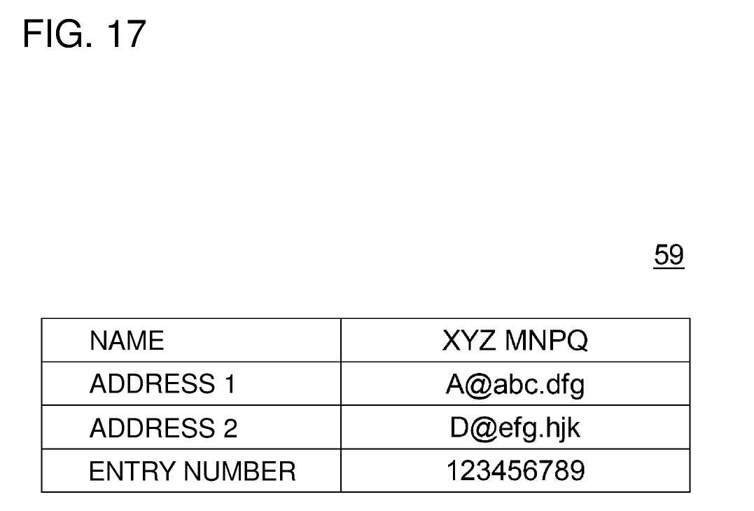

Step S12 will be described with reference to FIG. 17. The entry information 59 includes a name and an address 2. The entry information 59 may include an address 1 and an entry number. The name is the name of a customer. The address 1 is an email address of a customer. The address 2 is an email address of a trading company or a manufacturer prestored in the selection apparatus 10. The name and the address 1 are input by a customer using the input unit 19. The entry number is specific to each order.

The calculation unit 11 can generate an entry number specific to the selective tool model 38 in accordance with the number assigned to the selection apparatus 10, the order of entry, the entry date, or a random number list.

The communication unit 41 transmits the machining shape 25, the material 24, the finished product dimensions 27, and the selective tool model 38 to the address 2 through the Internet, a telephone network, or any other telecommunication network. When transmitting the information to the address 2, the communication unit 41 can transmit the entry number to the address 1. The communication unit 41 can also transmit the information transmitted to the address 2 to the address 1.

The advantageous effects of the present embodiment will now be described. An applicable burnishing tool type differs depending on the machining shape 25, the material 24, and the finished product dimensions 27. Further, the conditions under which a tool model is selected and a method for calculating such conditions differ depending on each burnishing tool type. In the present embodiment, the burnishing tool model is selected through entering information including the finished product dimensions 27 (steps S1 and S2), selecting the display tool type 34 (step S4), entering the specified tool type 28 (step S6), entering the specified conditions (step S8), and selecting the selective tool model 38 (step S10).

Further, the display tool type 34 is selected in step S4. A customer request is input in each of steps S6 and S8. The selective tool model 38 is then selected in step S10. The range of selectable tool models is narrowed through these steps, in each of which the corresponding conditions are calculated. This reduces the load on the selection apparatus 10.

The display tool type selection unit 15 selects the display tool type 34 based simply on the machining shape 25, the material 24, and the finished product dimensions 27. This allows the selectable range for the display tool type 34 to be narrowed early.

The display condition table 29 used in steps S3 and S4 is mainly divided into sections by the machining shape 25. Each section for the machining shape 25 is further categorized by the tool type. The display condition table 29 includes relation conditions and display conditions for the tool types to allow determination of whether each tool type is applicable. The display condition table 29 includes sections categorized by the machining shape 25 and includes relation conditions for each tool type. The display condition table 29 is thus used to determine whether each tool type is applicable to the target machining shape 25. The display condition table 29 includes all conditions to be used for determining whether each tool type is applicable. The display tool type selection unit 15 can thus select each of all the display tool types 34 applicable to the machining shape 25, the material 24, and the finished product dimensions 27 by referring to the display condition table 29.

In the present embodiment, a customer inputs the machining shape 25 using the entry screen 51 displayed on the output unit 39 in step S1. In step S2, the calculation unit 11 selects the finished product dimensions 27, which is to be used for selecting a burnishing tool model, and displays the selected finished product dimensions 27 on the entry screen 53. This eliminates the need for the customer to determine the dimensions.

A plurality of tool models are prepared for the machining shape 25, the material 24, and the finished product dimensions 27. To enable the tool model selection to reflect requests from a customer, the list screen 54 includes supplemental information, which can be used by the selection apparatus 10 to allow the selection method according to the present embodiment to reflect customer requests in selecting tool models.

The tool model table 35 also includes the branch conditions 37. In step S7, the output unit 39 outputs the branch conditions 37 included in the specified tool type 28 on the entry screen 56. The customer inputs the specified conditions 32 selected from the branch conditions 37. The tool model selection unit 17 can thus select a tool model that meets the customer requests based on the specified conditions 32.

The conditions used for selecting a burnishing tool model may be the machining conditions 26 including the tool diameter A. The machining conditions 26 are calculated (step S9) before a tool model is selected (step S10). This enables appropriate selection of the selective tool model 38.

The tool model table 35 includes various conditions to be used for selecting tool types, which are either the branch conditions 37 or the selection conditions 36. The branch conditions 37 are selected based on customer requests. The selection conditions 36 are selected in accordance with the machining shape 25, the material 24, the finished product dimensions 27, or the machining conditions 26. In other words, the selection conditions 36 are such conditions to be selected through complicated calculations, whereas the branch conditions 37 are such conditions not selectable by the selection apparatus 10, which are typically undefined and to be determined in accordance with the machine or customer requests. The conditions not selectable automatically by the selection apparatus 10 are selected by a customer. This enables the selection apparatus 10 to select an appropriate tool model.

A variety of burnishing tool types and models are available for different machining shapes 25. A tool model is to be selected based on existing data including machining data or based on experience. Although selecting a burnishing tool model may be difficult, the selection apparatus 10 or the selection method according to the present embodiment allows a customer to input definite information including the shape and the dimensions of a workpiece to be burnished in response to successive inquiries, and then allow display of a list of applicable options of the display tool types 34 on the list screen 54. The customer then selects the specified tool type 28 and the specified condition 32 in response to each inquiry to enable the selection apparatus 10 to select an applicable tool model easily. The above selection method provides an interactive approach to gradually narrow the range of selectable burnishing tools and to select an appropriate burnishing tool.

The present invention is not limited to the above-described embodiments, and various modifications are possible without departing from the gist of the present invention, and all technical matters included in the technical concept described in the claims are encompassed by the present invention. While specific embodiments have been described, those skilled in the art may practice various alternatives, modifications, alterations, or improvements from the disclosure described herein, and all such variations fall within the scope of the invention defined by the appended claims.

### REFERENCE SIGNS LIST

10 selection apparatus
11 calculation unit
13 machining condition calculation unit
15 display tool type selection unit
17 tool model selection unit
19 input unit
23 storage unit
24 material
25 machining shape
26 machining condition
27 finished product dimension
28 specified tool type
29 display condition table
31 supplemental information table
32 specified condition
33 machining condition calculation table
34 display tool type
35 tool model table
37 branch condition
38 selective tool model
39 output unit

What is claimed is:

1. A method for selecting a burnishing tool model, the method comprising:
receiving, by an input unit, a machining shape, a material, and a finished product dimension;
selecting, by a display tool type selection unit, at least one display tool type satisfying a display condition based on the input machining shape, the input material, and the input finished product dimension, and a display condition table stored in a storage unit;
receiving, by the input unit, a specified tool type selected from the at least one display tool type output from an output unit;
receiving, by the input unit, a specified condition selected from at least one branch condition assigned to the specified tool type output from the output unit based on the specified tool type and a tool model table including the at least one branch condition for selecting at least one tool model, the tool model table being stored in the storage unit;
selecting, by a tool model selection unit, a tool model as a selective tool model applicable to the machining shape, the finished product dimension, and the specified condition from the at least one tool model included in the tool model table for the specified tool type; and
outputting, by the output unit, the selective tool model.

2. The method for selecting a burnishing tool model according to claim 1, further comprising:
calculating, by the display tool type selection unit, a comparison value in the display condition table based on the input machining shape, the input material, and the input finished product dimension, and the display condition table stored in the storage unit.

3. The method for selecting a burnishing tool model according to claim 1, wherein
the display condition table includes, for each machining shape and for each tool type, the finished product dimension to be compared, the comparison value to be compared with the finished product dimension to be compared, and a relation condition.

4. The method for selecting a burnishing tool model according to claim 1, wherein
the calculating the comparison value includes obtaining the comparison value using a comparison value calculation function that uses the finished product dimension as an argument.

5. The method for selecting a burnishing tool model according to claim 1, wherein
the tool model includes a selection condition including an applicable range of the finished product dimension, and the method further comprising:
the selecting the tool model performed further includes selecting, by the tool model selection unit, a tool model as the selective tool model for which the finished product dimension corresponding to the selection condition satisfies the selection condition.

6. The method for selecting a burnishing tool model according to claim 5, further comprising:
calculating, by a machining condition calculation unit, a machining condition based on the machining shape, the finished product dimension, the specified tool type, the specified condition, and a machining condition calculation table stored in the storage unit.

7. The method for selecting a burnishing tool model according to claim 6, wherein
the selection condition includes an applicable range of the machining condition.

8. The method for selecting a burnishing tool model according to claim 1, further comprising:
displaying supplemental information for the display tool type together with the display tool type.

9. The method for selecting a burnishing tool model according to claim 2, wherein
the display condition table includes, for each machining shape and for each tool type, the finished product dimension to be compared, the comparison value to be compared with the finished product dimension to be compared, and a relation condition.

10. The method for selecting a burnishing tool model according to claim 2, wherein
the calculating the comparison value includes obtaining the comparison value using a comparison value calculation function that uses the finished product dimension as an argument.

11. The method for selecting a burnishing tool model according to claim 3, wherein
the calculating the comparison value includes obtaining the comparison value using a comparison value calculation function that uses the finished product dimension as an argument.

12. The method for selecting a burnishing tool model according to claim 2, wherein
the tool model includes a selection condition including an applicable range of the finished product dimension, and the method further comprising:
the selecting the tool model performed further includes selecting, by the tool model selection unit, a tool model as the selective tool model for which the finished product dimension corresponding to the selection condition satisfies the selection condition.

13. The method for selecting a burnishing tool model according to claim 3, wherein
the tool model includes a selection condition including an applicable range of the finished product dimension, and the method further comprising:
the selecting the tool model performed further includes selecting, by the tool model selection unit, a tool model as the selective tool model for which the finished product dimension corresponding to the selection condition satisfies the selection condition.

14. The method for selecting a burnishing tool model according to claim 4, wherein
the tool model includes a selection condition including an applicable range of the finished product dimension, and the method further comprising:
the selecting the tool model performed further includes selecting, by the tool model selection unit, a tool model as the selective tool model for which the finished product dimension corresponding to the selection condition satisfies the selection condition.

15. The method for selecting a burnishing tool model according to claim 12, further comprising:
calculating, by a machining condition calculation unit, a machining condition based on the machining shape, the finished product dimension, the specified tool type, the specified condition, and a machining condition calculation table stored in the storage unit.

16. The method for selecting a burnishing tool model according to claim 13, further comprising:
calculating, by a machining condition calculation unit, a machining condition based on the machining shape, the finished product dimension, the specified tool type, the specified condition, and a machining condition calculation table stored in the storage unit.

17. The method for selecting a burnishing tool model according to claim 14, further comprising:
calculating, by a machining condition calculation unit, a machining condition based on the machining shape, the finished product dimension, the specified tool type, the specified condition, and a machining condition calculation table stored in the storage unit.

18. The method for selecting a burnishing tool model according to claim 15, wherein
the selection condition includes an applicable range of the machining condition.

19. A selection apparatus for selecting a burnishing tool model, the apparatus comprising:
a storage unit configured to store a tool model table including a tool model that belongs to a tool type, at least one branch condition for the tool model included in the tool model table, and a display condition table including a comparison value and a display condition for the tool type in accordance with a machining shape;
an input unit configured to receive an input of the machining shape, a material, a finished product dimension, at least one specified tool type selected from at least one display tool type, and a specified condition selected from the at least one branch condition;
a calculation unit including
a display tool type selection unit configured to select the tool type satisfying the display condition as a display tool type based on the machining shape, the finished product dimension, and the display condition table, and
a tool model selection unit configured to select the tool model applicable to the material, the finished product dimension, and the specified condition from the at least one specified tool type as a selective tool model based on the material, the finished product dimension, the specified tool type, the specified condition, and the tool model table; and
an output unit configured to output the display tool type, the branch condition, and the selective tool model.

20. A non-transitory computer-readable storage medium storing a program for selecting a burnishing tool model, the program causing a computer to implement:
receiving, by an input unit, a machining shape, a material, and a finished product dimension;
selecting, by a display tool type selection unit, at least one display tool type satisfying a display condition based on the input machining shape, the input material, and the input finished product dimension, and a display condition table stored in a storage unit;
receiving, by the input unit, a specified tool type selected from the at least one display tool type output from an output unit;
receiving, by the input unit, a specified condition selected from at least one branch condition assigned to the specified tool type output from the output unit based on the specified tool type and a tool model table including the at least one branch condition for selecting at least one tool model, the tool model table being stored in the storage unit;
selecting, by a tool model selection unit, a tool model as a selective tool model applicable to the machining shape, the finished product dimension, and the specified condition from the at least one tool model included in the tool model table for the specified tool type; and
outputting, by the output unit, the selective tool model.
